(19) United States
(12) Patent Application Publication
(10) Pub. No.: US 2025/0125794 A1
(43) Pub. Date: Apr. 17, 2025

(54) SYSTEM AND METHOD FOR PULSE GENERATION DURING QUANTUM OPERATIONS

(71) Applicant: Quantum Machines, Tel Aviv (IL)

(72) Inventors: Itamar Sivan, Tel Aviv (IL); Yonatan Cohen, Tel Aviv (IL); Nissim Ofek, Tel Aviv (IL); Nir Halay, Tel Aviv (IL); Ori Weber, Tel Aviv (IL)

(21) Appl. No.: 18/928,277

(22) Filed: Oct. 28, 2024

Related U.S. Application Data
(63) Continuation of application No. 17/225,651, filed on Apr. 8, 2021, now Pat. No. 12,132,486.

(51) Int. Cl. H03K 3/38; G06N 10/00; H03K 5/19

(52) U.S. Cl. CPC H03K 3/38; G06N 10/00; H03K 5/19

(57) ABSTRACT

A pulse generation circuit in a quantum controller operates synchronously with a pulse computation circuit. The pulse generation circuit generates a pulse associated with a quantum element operation. The pulse computation circuit is able to determine characteristics of a signal that is based on the pulse. These characteristics are used by the pulse generation circuit to modify the pulse.

### CROSS-REFERENCE TO RELATED APPLICATIONS

Co-pending application Ser. No. 17/020,135, filed Sep. 14, 2020 is incorporated herein by reference in its entirety.

### BACKGROUND

Limitations and disadvantages of conventional quantum controllers will become apparent to one of skill in the art, through comparison of such approaches with some aspects of the present method and system set forth in the remainder of this disclosure with reference to the drawings.

### BRIEF SUMMARY

Methods and systems are provided for pulse generation in a quantum controller, substantially as illustrated by and/or described in connection with at least one of the figures, as set forth more completely in the claims.

### BRIEF DESCRIPTION OF THE DRAWINGS

FIG. 1 illustrates an example system for pulse generation and pulse computation during quantum operations in accordance with various example implementations of this disclosure.

FIG. 2 illustrates an example RF circuit that may be operably coupled to a system for pulse generation during quantum operations in accordance with various example implementations of this disclosure.

FIG. 3 illustrates an example time-tagger block for use in pulse computation during quantum operations in accordance with various example implementations of this disclosure.

FIG. 4 illustrates a flowchart of an example method for pulse generation and pulse computation during quantum operations in accordance with various example implementations of this disclosure.

### DETAILED DESCRIPTION

Classical computers operate by storing information in the form of binary digits (“bits”) and processing those bits via binary logic gates. At any given time, each bit takes on only one of two discrete values: 0 (or “off”) and 1 (or “on”). The logical operations performed by the binary logic gates are defined by Boolean algebra and circuit behavior is governed by classical physics. In a modern classical system, the circuits for storing the bits and realizing the logical operations are usually made from electrical wires that can carry two different voltages, representing the 0 and 1 of the bit, and transistor-based logic gates that perform the Boolean logic operations.

Logical operations in classical computers are performed on fixed states. For example, at time 0 a bit is in a first state, at time 1 a logic operation is applied to the bit, and at time 2 the bit is in a second state as determined by the state at time 0 and the logic operation. The state of a bit is typically stored as a voltage (e.g., 1 V_{dc} for a “1” or 0 V_{dc} for a “0”). The logic operation typically comprises of one or more transistors.

Obviously, a classical computer with a single bit and single logic gate is of limited use, which is why modern classical computers with even modest computation power contain billions of bits and transistors. That is to say, classical computers that can solve increasingly complex problems inevitably require increasingly large numbers of bits and transistors and/or increasingly long amounts of time for carrying out the algorithms. There are, however, some problems which would require an infeasibly large number of transistors and/or infeasibly long amount of time to arrive at a solution. Such problems are referred to as intractable.

Quantum computers operate by storing information in the form of quantum bits (“qubits”) and processing those qubits via quantum gates. Unlike a bit which can only be in one state (either 0 or 1) at any given time, a qubit can be in a superposition of the two states at the same time. More precisely, a quantum bit is a system whose state lives in a two dimensional Hilbert space and is therefore described as a linear combination α|0 [symbol] +β|1 [symbol] , where |0 [symbol] and |1 [symbol] are two basis states, and α and β are complex numbers, usually called probability amplitudes, which satisfy |α|²+|β|²=1. Using this notation, when the qubit is measured, it will be 0 with probability |α|² and will be 1 with probability |β|². The basis states |0 [symbol] and |1 [symbol] can also be represented by two-dimensional basis vectors

$$[ \begin{matrix}1 \\ 0\end{matrix} ] and [ \begin{matrix}0 \\ 1\end{matrix} ] ,$$

respectively. The qubit state may represented by

$$[ \begin{matrix}α \\ β\end{matrix} ] .$$

The operations performed by the quantum gates are defined by linear algebra over Hilbert space and circuit behavior is governed by quantum physics. This extra richness in the mathematical behavior of qubits and the operations on them, enables quantum computers to solve some problems much faster than classical computers. In fact, some problems that are intractable for classical computers may become trivial for quantum computers.

Unlike a classical bit, a qubit cannot be stored as a single voltage value on a wire. Instead, a qubit is physically realized using a two-level quantum mechanical system. For example, at time 0 a qubit is described as

$$[ \begin{matrix}{α}_{1} \\ {β}_{1}\end{matrix} ] ,$$

at time 1 a logic operation is applied to the qubit, and at time 2 the qubit is described as

$$[ \begin{matrix}{α}_{2} \\ {β}_{2}\end{matrix} ] .$$

Many physical implementations of qubits have been proposed and developed over the years. Some examples of qubits implementations include superconducting circuits, spin qubits, and trapped ions.

A quantum orchestration platform (QOP) may comprise a quantum controller (QC), a quantum programming subsystem and a quantum processor.

It is the job of a QC to generate the precise series of external signals, usually pulses of electromagnetic waves and pulses of base band voltage, to perform the desired logic operations (and thus carry out the desired quantum algorithm).

The quantum programming subsystem comprises circuitry operable to generate a quantum algorithm description which configures the QC and includes instructions the QC can execute to carry out the quantum algorithm (i.e., generate the necessary outbound quantum control pulse(s)) with little or no human intervention during runtime. In an example implementation, the quantum programming system is a personal computer comprising a processor, memory, and other associated circuitry (e.g., an x86 or x64 chipset). The quantum programming subsystem then compiles the high-level quantum algorithm description to a machine code version of the quantum algorithm description (i.e., series of binary vectors that represent instructions that the QC's hardware can interpret and execute directly).

The quantum programming subsystem may be coupled to the QC via an interconnect which may, for example, utilize a universal serial bus (USB), a peripheral component interconnect (PCIe) bus, wired or wireless Ethernet, or any other suitable communication protocol.

The QC comprises circuitry operable to load the machine code quantum algorithm description from the programming subsystem via the interconnect. Then, execution of the machine code by the QC causes the QC to generate the necessary outbound quantum control pulse(s) that correspond to the desired operations to be performed on the quantum processor (e.g., sent to qubit(s) for manipulating a state of the qubit(s) or to readout resonator(s) for reading the state of the qubit(s), etc.). Depending on the quantum algorithm to be performed, outbound pulse(s) for carrying out the algorithm may be predetermined at design time and/or may need to be determined during runtime. The runtime determination of the pulses may comprise performance of classical calculations and processing in the QC during runtime of the algorithm (e.g., runtime analysis of inbound pulses received from the quantum processor).

During runtime and/or upon completion of a quantum algorithm performed by the QC, the QC may output data/results to the quantum programming subsystem. In an example implementation these results may be used to generate a new quantum algorithm description for a subsequent run of the quantum algorithm and/or update the quantum algorithm description during runtime. Inputs from the quantum programming subsystem may also be pulled to the QC.

A QC comprises a plurality of pulse processors, which may be implemented in a field programmable gate array, an application specific integrated circuit or the like. A pulse processor is operable to generate and control outbound pulses that drive a quantum element (e.g., one or more qubits and/or resonators). A pulse processor is also operable to receive and analyze inbound pulses from a quantum element.

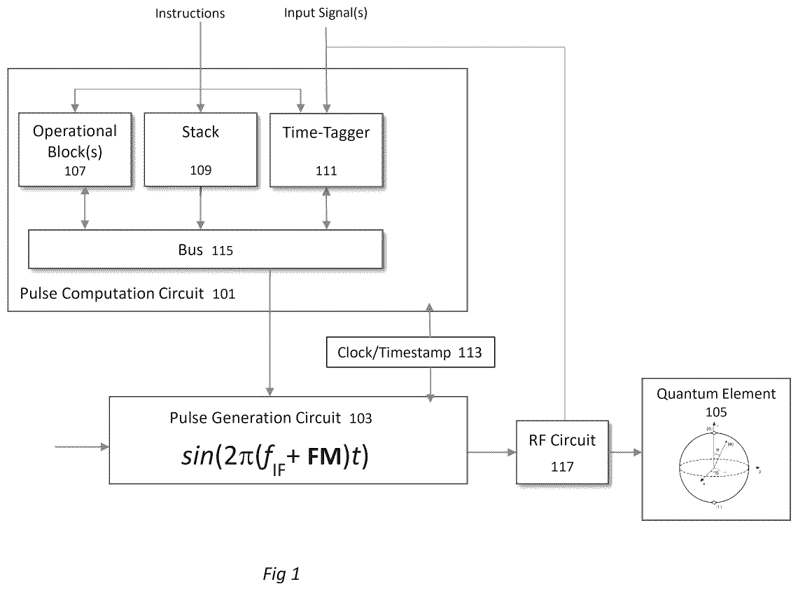

FIG. 1 illustrates an example pulse processor system for pulse generation and pulse computation during quantum operations in accordance with various example implementations of this disclosure.

The pulse processor in FIG. 1 comprises a pulse computation circuit 101 and a pulse generation circuit 103. The pulse generation circuit 103 generates an outbound pulse associated with a quantum element operation. The outbound pulse may be a frequency modulated (FM) intermediate frequency (IF) signal of the form sin (2π(f_{IF}+FM)t), where f_{IF} is a selectable IF. The outbound pulse is transmitted to a quantum element 105 via an RF circuit 117.

The pulse computation circuit 101 is operational while the pulse generation circuit 103 generates the outbound pulse. The pulse computation circuit 101 comprises a bus 115 and a plurality of operational blocks 107, 109, 111. The operational blocks 107, 109, 111 of the pulse computation circuit 101 generate results that are routed to the bus 115. The bus 115 is a register level which stores all of the operational block results. The bus vectors are used by the operational blocks 107, 109, 111 for further computation. Results may be dispatched from the bus 115 to various destinations.

One of the operational blocks may be a stack block 109. The stack block 109 is able to select a register vector from the bus 115. The stack block 109 is also able to perform a push, pull or peek operation to determine latency.

The pulse computation circuit 101 and pulse generation circuit 103 maintain time and frequency synchronization using a clock/timestamp 113. The clock/timestamp 113 comprises an internal system clock that maintains the exact same phase within the pulse computation circuit 101 and pulse generation circuit 103. The clock/timestamp 113 also manages a timestamp that holds the same value for both the pulse computation circuit 101 and the pulse generation circuit 103. Operations are synchronized through reading the current timestamp and holding control registers in the bus 115. For example, a phase increment may be multiplied by the timestamp to generate a global phase accumulated. This enables a frequency basis with respect to an absolute t=0, thereby allowing a seamlessly switching between frequencies while keeping a global phase that progresses in a deterministic fashion.

The pulse computation circuit 101 may receive instructions and execute a program to analyze an input signal to determine its characteristics. Such an input signal may be derived from the outbound pulse. For example, the input signal may be a response from a quantum element. The input signal may be a baseband or IF signal downconverted from RF. The input signal may a single channel or may be in a dual channel I/Q format.

Another of the operational blocks is a time-tagger block 111 that is able to associate a timestamp with each sample of the input signal and determine a characteristic of the input signal. For example, the time-tagger block may determine an arrival time of a rising-edge and/or a falling-edge of the input signal. The time-tagger block may also determine the number of zero crossings of the input signal during a period of time.

The pulse generation circuit 103 modifies one or more parameters of the outbound pulse according to the determined characteristics from the pulse computation circuit 101. The determined characteristics may be selectively dispatched from the bus 116 as one or more results.

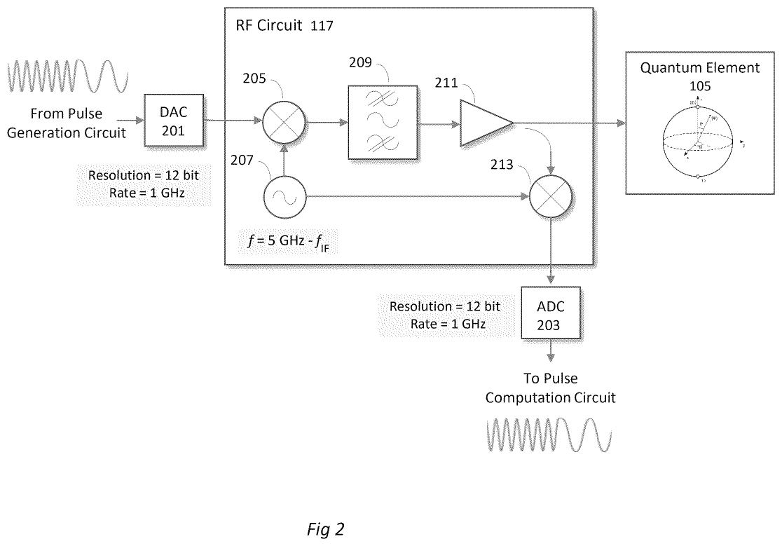

FIG. 2 illustrates an example RF circuit 117 that may be operably coupled to a pulse generation circuit 103 (of FIG. 1) during quantum operations in accordance with various example implementations of this disclosure.

The RF circuit 117 comprises a mixer 205, an oscillator 207, a bandpass filter 209 and an amplifier 211. The outbound pulse from pulse generation circuit 103 (of FIG. 1) is converted from digital to analog with DAC 201. For example, the DAC 201 may convert 12 bit digital samples at a rate of 1 GHz. The DAC 201 may comprise a digital interpolator. The interpolation may be, for example, third-order interpolation. The DAC 201 may be located in the pulse generation circuit 103 (of FIG. 1), in the RF circuit 117 or in a stand-alone device. The analog output of the DAC 201 is converted to RF (e.g., ˜5 GHZ) in mixer 205. The RF signal is filter in bandpass filter 209 and amplified in amplifier 211. The output of the amplifier 211 is used for an operation on quantum element 105.

The operation on quantum element 105 is highly dependent on an exact phase. However, the mixer 205, the oscillator 207, the bandpass filter 209 and the amplifier 211 may introduce a phase perturbation. A feedback to the pulse generation circuit 103 (of FIG. 1) controls such phase perturbations. The RF signal output from the amplifier 211 may be down converted by mixer 213. While mixer 213 is illustrated as being connected to oscillator 207, mixer 213 may also use a slightly higher or lower frequency, such that the IF input to mixer 205 is offset from the IF output from mixer 213. Non-ideal responses caused by the introduction of mixer 213 may be calibrated out prior to system operation. The analog IF output from mixer 213 is sampled by ADC 203. For example, ADC 203 may generate 12 bit digital samples at a rate of 1 GHz. The digital samples are coupled the pulse computation circuit 101 (of FIG. 1). ADC 203 may be located in the pulse computation circuit 101 (of FIG. 1), in the RF circuit 117 or in a stand-alone device.

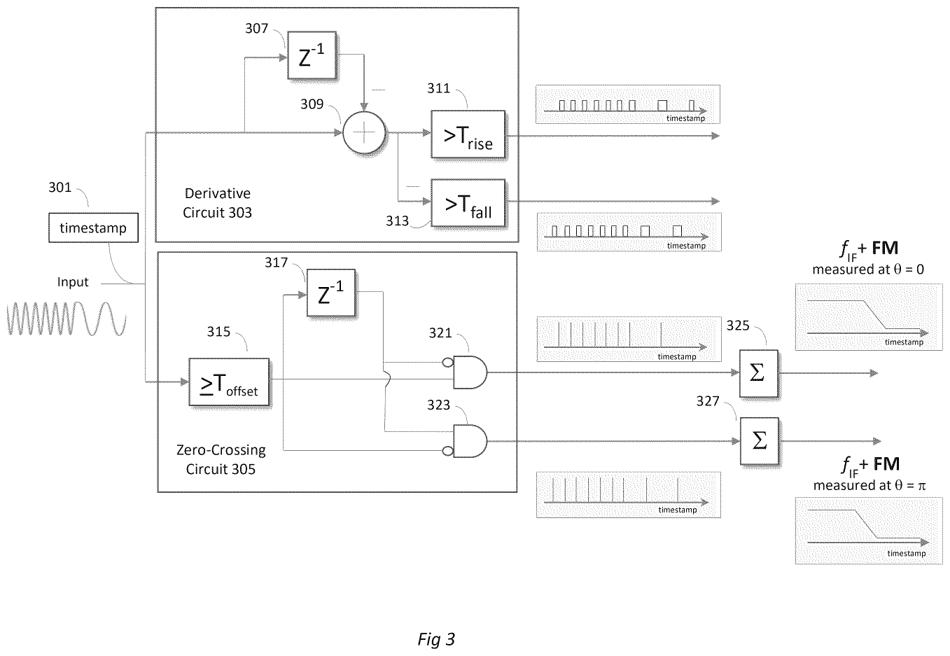

FIG. 3 illustrates an example time-tagger block 111 (of FIG. 1) for use in pulse computation during quantum operations in accordance with various example implementations of this disclosure. The time-tagger block 111 (of FIG. 1) associates a timestamp 301 with each sample of the input signal. The time-tagged samples are analyzed in a derivative circuit 303 and a zero-crossing circuit 305.

The derivative circuit 303 comprises a subtractor 309 for determining an estimate of a derivative of the input signal. A current sample is compared with a previous sample as provided by delay 307. Alternatively the subtractor 309 may operate on a parallel sequence of samples. The subtractor 309 output is then compared to a threshold, Tᵣᵢₛₑ, 311 to determine whether the derivative is positive (i.e., the input is rising). In some situations, Tᵣᵢₛₑ may be set to 0, and the derivative is determined by threshold, Tᵣᵢₛₑ, 311 to be positive or negative. Tᵣᵢₛₑ may also be set above noise floor. In this case, the subtractor 309 output is inverted and compared to a threshold, T_{fall}, 313 to determine whether the derivative is negative (i.e., the input is falling). The output results from threshold, Tᵣᵢₛₑ, 311 and threshold, T_{fall}, 313 are sent to bus 111 (in FIG. 1) and are available for further computations. The threshold, Tᵣᵢₛₑ, 311 output indicates the location of the rising edge of the input signal. The threshold, T_{fall}, 313 output indicates the location of the falling-edge of the input signal. A timestamp may be associated with each threshold crossing.

The zero-crossing circuit 305 detects when ADC data crosses a threshold value, T_{offset} at comparator 315. Tᵣᵢₛₑ, T_{fall} and T_{offset} may be maintained in (and be accessed from) bus 111. T_{offset} may be set to 0 if the input signal is centered at zero. Otherwise, T_{offset} may be set according to a DC bias of the input signal. A current output from comparator 315 is compared with a previous output from comparator 315 as provided by delay 317. A “01” sequence, as indicated at logic gate 321, is a crossing of T_{offset} from a lower value to a higher value. A “10” sequence, as indicated at logic gate 323, is a crossing of T_{offset} from a higher value to a lower value. The output results from logic gate 321 and logic gate 323 are sent to bus 111 (in FIG. 1) and are available for further computations.

The time-tagger block may also determine the number of threshold crossings of the input signal during a selectable period of time. The output of counter/summer 325 is an estimate of f_{IF}+FM as measured at a phase of 0. The output of counter/summer 327 is an estimate of f_{IF}+FM as measured at a phase of π. The output results from counter/summer 325 and counter/summer 327 are sent to bus 111 (in FIG. 1) and are available for further computations. For example, the output results from counter/summer 325 and counter/summer 327 may indicate desired or undesired phase perturbations.

The input signal may be digitally sampled and then also interpolated in order to increase the resolution of the time tagging. The time-tagger block would, therefore, be configured to determine a number of threshold crossings in an interpolated version of the input signal.

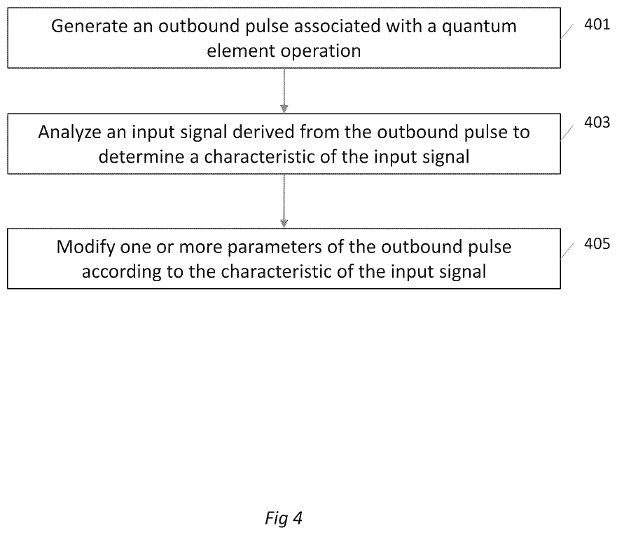

FIG. 4 illustrates a flowchart of an example method for pulse generation and pulse computation during quantum operations in accordance with various example implementations of this disclosure.

At step 401, an outbound pulse associated with a quantum element operation is generated in a pulse generation circuit.

A pulse computation circuit is operational while the pulse generation circuit generates the outbound pulse. At step 403, the pulse computation circuit executes a program to analyze an input signal to determine its characteristics. The input signal may be derived from the outbound pulse. The pulse computation circuit comprises a plurality of operational blocks and a bus. The one or more operational blocks of the pulse computation circuit generate results that are routed to the bus.

The plurality of operational blocks comprise a time-tagger block that is able to associate a timestamp with each sample of an input signal and determine a characteristic of the input signal. For example, the time-tagger block may determine a rising-edge and/or a falling-edge of the input signal. The time-tagger block may also determine the number of zero crossings of the input signal during a period of time.

At step 405, the pulse generation circuit modifies one or more parameters of the outbound pulse according to the determined characteristics. The determined characteristics may be selectively dispatched from the bus as one or more results.

The plurality of operational blocks may comprise a stack block that is able to select a register vector from the bus. The stack block is also able to perform a push, pull or peek operation to determine latency.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

As used herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As used herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As used herein, the term “exemplary” means serving as a non-limiting example, instance, or illustration. As used herein, the terms “e.g.,” and “for example” set off lists of one or more non-limiting examples, instances, or illustrations. As used herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.). As used herein, the term “based on” means “based at least in part on.” For example, “x based on y” means that “x” is based at least in part on “y” (and may also be based on z, for example).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1-22. (canceled)

23. A system comprising:
a pulse generation circuit configured to generate an outbound pulse associated with a first quantum element operation; and
a time-tagger circuit configured to determine a number of threshold crossings in an input signal associated with a second quantum element operation.

24. The system of claim 23, wherein the time-tagger circuit is configured to determine an arrival time of a rising-edge of the input signal.

25. The system of claim 23, wherein the time-tagger circuit is configured to determine an arrival time of a falling-edge of the input signal.

26. The system of claim 23, wherein the time-tagger circuit is configured to digitally sample and interpolate the input signal.

27. The system of claim 23, wherein the time-tagger circuit is configured to associate a timestamp to each of a plurality of threshold crossings of the input signal.

28. The system of claim 23, wherein the system comprises a pulse computation circuit comprising a bus and a plurality of operational blocks.

29. The system of claim 28, wherein the pulse computation circuit is configured to execute a program while the pulse generation circuit generates the outbound pulse.

30. The system of claim 28, wherein the pulse computation circuit is configured to selectively dispatch one or more results from the plurality of operational blocks.

31. The system of claim 28, wherein the plurality of operational blocks comprises a stack block configured to select a register vector from the bus.

32. The system of claim 28, wherein the plurality of operational blocks comprises a stack block, associated with a deterministic latency, configured to perform one or more of:
a push operation,
a pull operation, and
a peek operation.

33. A method comprising:
generating, via a pulse generation circuit, an outbound pulse associated with a first quantum element operation; and
determining, using a time-tagger circuit, a number of threshold crossings in an input signal associated with a second quantum element operation.

34. The method of claim 33, wherein the method comprises determining, using the time-tagger circuit, an arrival time of a rising-edge of the input signal.

35. The method of claim 33, wherein the method comprises determining, using the time-tagger circuit, an arrival time of a falling-edge of the input signal.

36. The method of claim 33, wherein the method comprises digitally sampling and interpolating the input signal, using the time-tagger circuit.

37. The method of claim 33, wherein the method comprises associating a timestamp to each of a plurality of threshold crossings of the input signal, using the time-tagger circuit.

38. The method of claim 33, wherein a pulse computation circuit comprises a bus, the time-tagger circuit, and a stack block.

39. The method of claim 38, wherein the method comprises executing a program, via the pulse computation circuit, while the pulse generation circuit generates the outbound pulse

40. The method of claim 38, wherein the method comprises selectively dispatching one or more results from the pulse computation circuit.

41. The method of claim 38, wherein the method comprises selecting a register vector from the bus via the stack block.

42. The method of claim 38, wherein the method comprises performing, via the stack block, one or more of:
a push operation,
a pull operation, and
a peek operation.
